(19) United States
(12) Patent Application Publication
(10) Pub. No.: US 2013/0028283 A1
(43) Pub. Date: Jan. 31, 2013

(54) HIGH SPEED VERTICAL-CAVITY SURFACE-EMITTING LASER

(71) Applicants: Wolfgang Kaiser, Zurich (CH); Jörg Troger, Raron (CH); Michael Moser, Baden (CH)

(72) Inventors: Wolfgang Kaiser, Zurich (CH); Jörg Troger, Raron (CH); Michael Moser, Baden (CH)

(21) Appl. No.: 13/416,981

(22) Filed: Mar. 9, 2012

(30) Foreign Application Priority Data
Jul. 27, 2011 (GB) 1112927.7

(51) Int. Cl. H01S 5/125

(52) U.S. Cl. 372/50.11

(57) ABSTRACT

There is described a high speed vertical-cavity surface-emitting laser (VCSEL) comprising a substrate and first and second distributed Bragg reflectors (DBRs) disposed on the substrate, each comprising a stack of layers of alternating refractive index. A resonant cavity is disposed between the DBRs and an active region disposed in the resonant cavity. The resonant cavity is formed of material having low refractive index and has an optical thickness in a direction perpendicular to the substrate of ½λ, where λ is the wavelength of light emitted by the VCSEL.

### CROSS-REFERENCE TO RELATED APPLICATIONS

This application claims benefit of British patent application number 1112927.7, filed Jul. 27, 2011, which is herein incorporated by reference.

### BACKGROUND OF THE INVENTION

1. Field of the Invention

The invention relates to high speed vertical-cavity surface-emitting lasers (VCSELs).

2. Description of the Related Art

In this specification the term “light” will be used in the sense that it is used in optical systems to mean not just visible light, but also electromagnetic radiation having a wavelength outside that of the visible range.

The ever-increasing bandwidth-distance requirements of communication systems have resulted in data being transmitted over optical fibres. Both conventional telecommunications and data networks such as the Internet use optical fibres for both short and long distance transmission. Optical communication channels provide extremely high data rates (in excess of 10 Gbit/s or even 25 Gbit/s). Data that is to be sent down such channels is typically generated in the form of electrical signals that are converted to optical signals by directly modulating a laser at one end of an optical fibre.

Vertical Cavity Surface Emitting Lasers (VCSELs) have become commercially important as transmitters in such high bit rate (>1 Gbit/s) optical communication links. A VCSEL is a semiconductor laser device including one or more semiconductor layers (typically quantum wells) exhibiting an appropriate band gap structure to emit light in a desired wavelength range perpendicularly to the one or more semiconductor layers. Typically, the thickness of a corresponding semiconductor layer is in the range of a few nanometres. In the case of a multi-quantum well laser, the thickness and the strain created during the formation of the stack of semiconductor layers having, in an alternating fashion, a different gap, determine the position of the energy level in the quantum wells of the conduction bands and valence bands defined by the layer stack. The position of the energy levels defines the wavelength of the radiation that is emitted by recombination of an electron-hole-pair confined in the respective quantum wells. Unlike in edge emitting semiconductor laser devices, the current flow and the light propagation occurs in a vertical direction with respect to the semiconductor layers. Above and below the semiconductor layers respective mirrors, also denoted as top and bottom mirrors, wherein the terms “top” and “bottom” are exchangeable, are provided and form a resonator to define an optical cavity. The laser radiation established by the resonator is coupled out through that mirror having the lower reflectivity.

Although VCSEL devices suffer from relatively low output power due to their small laser cavity, VCSELs are steadily gaining in importance in a variety of technical fields, since a VCSEL device exhibits a number of advantages when compared to a conventional double heterostructure laser diode, also referred to as edge-emitting lasers. First, a large number of VCSEL devices can be fabricated and entirely tested on the initial substrate, so that a significant reduction in manufacturing costs is obtained compared to edge-emitting lasers. Second, the overall volume of a single VCSEL device is reduced by a factor of about 10-100 compared to the double heterostructure laser diode. Third, due to the extremely small volume of the gain region that is defined in the vertical direction by the thickness of the semiconductor layers having in alternating fashion a different band gap, the current for operating the VCSEL device is in the range of a few milliamps, whereby a high efficiency of conversion of current into light is achieved. Fourth, a further VCSEL device exhibits a relatively low beam divergence, which allows a high coupling efficiency to other optical components, such as optical fibres, without the necessity of additional converging optical elements.

Increasingly high speed VCSELS are required for high modulation at low currents. 10 Gbit/s VCSELs have become successful, but future needs for link capacities of 100 Gbit/s aggregate bandwidth create a demand for VCSELs capable of even higher modulation speeds.

FIG. 1 illustrates the structure of a typical high speed VCSEL 100. On a substrate 101 is an n-doped mirror 102 formed by alternating layers of high refractive index material 103 and low refractive index material 104 so as to produce a high reflectivity Distributed Bragg Reflector (DBR). A p-doped mirror 105, also formed as a DBR by alternating high and low refractive index layers 103, 104, is located above the n-doped mirror 102, with a resonant cavity 106 formed therebetween. The cavity includes an active (gain) region 107 comprising one or more quantum well layers separated by barrier layers. An oxide layer 108 defining an aperture 109 is located between the cavity 106 and the p-mirror 105. In this example it can be seen that the oxide layer 108 and p-mirror 105 form a mesa. The VCSEL 100 also includes a cap layer 110 on top of the p-mirror 105.

The cavity 106 usually has an optical thickness equal to the wavelength λ (or an integral number of wavelengths) of the light emitted by the laser. The material in the cavity generally has a low bandgap (and high refractive index) so there are many carriers. FIG. 2A illustrates the cavity 200 having a width of one wavelength. FIGS. 2B and 2C illustrate the bandgap 201 and refractive index 202, respectively, of the cavity 200 (including the active layer) of FIG. 2A. In general, the material 203 of the cavity on either side of the quantum well 204 (typically of width of the order 100-200 nm) acts as a “buffer” which reduces strain in the quantum wells.

FIG. 3 illustrates the location of the electric field standing wave 301 and the bandgap 302 of a cavity of the type described above.

VCSELs for wavelengths from 650 nm to 1300 nm are typically based on gallium arsenide (GaAs) wafers with DBRs formed from GaAs and aluminium gallium arsenide (AlₓGa₍₁₋ₓ₎As). The GaAs—AlGaAs system is favoured for constructing VCSELs because the lattice constant of the material does not vary strongly as the composition is changed, permitting multiple “lattice-matched” epitaxial layers to be grown on a GaAs substrate. However, the refractive index of

AlGaAs does vary relatively strongly as the Al fraction is increased, minimizing the number of layers required to form an efficient Bragg mirror compared to other candidate material systems. Furthermore, at high aluminium concentrations, an oxide can be formed from AlGaAs, and this oxide can be used to restrict the current in a VCSEL, enabling very low threshold currents.

There is a need to increase the speed of high speed VCSELs such as those shown in FIG. 1 even further.

### SUMMARY OF THE INVENTION

In accordance with one aspect of the present invention there is provided a high speed VCSEL comprising a substrate and first and second DBRs disposed on the substrate, each comprising a stack of layers of alternating refractive index. A resonant cavity is disposed between the DBRs and an active region disposed in the resonant cavity. The resonant cavity is formed of material having low refractive index and has an optical thickness in a direction perpendicular to the substrate of ½λ, where λ is the wavelength of light emitted by the VCSEL. The carrier delay in the cavity is 100 ps or less.

In one embodiment the VCSEL may be fabricated using the AlGaAs/GaAs system, although it will be appreciated that other systems such as AlGaInIsP/GaAs, AlGaInNAsP/GaAs and InGaAsP/GaAs inter alia are also possible. At least one oxide layer may be provided in either or both of the DBRs. The cavity may be formed from Al doped material and optionally does not include any oxide. The Al material composition of the cavity is optionally at least 1% less than the Al composition of the oxide layer. The VCSEL may be configured to emit light modulated at rate of at least 10 Gbit/s, preferably at least 15 Gbit/s, more preferably at least 25 Gbit/s. The wavelength of light emitted may be in the range from 650 nm to 1.5 μm, and is optionally 850 nm.

The distance between the active region and the low refractive index region of the cavity may be in the range 0 to 50 nm, preferably 0 to 25 nm, more preferably 5-15 nm. This may result in strain in quantum wells in the active region.

The cavity may be disposed between two barrier layers, each barrier layer having a bandgap energy which is less than that of the cavity by a difference of 2 kT or greater, preferably 5 kT, 10 kT or 20 kT or greater.

In accordance with another aspect of the present invention there is provided a method of generating modulated light, comprising injecting current into an active region of a VCSEL. The active region is located in a resonant cavity disposed between first and second DBRs. The cavity is formed of material having low refractive index and has an optical thickness of ½λ, where λ is the wavelength of light emitted by the VCSEL. The injected current is modulated at a rate of at least 5 Gbit/s, and optionally at 15 Gbit/s or higher.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of a prior art high speed VCSEL.

FIGS. 2A, 2B and 2C illustrate the thickness, bandgap and refractive index of a cavity of the VCSEL of FIG. 1.

FIG. 3 is a schematic illustration of the bandgap and electric field distribution in a VCSEL similar to that shown in FIG. 1.

FIG. 4 is a schematic illustration of an improved high speed VCSEL.

FIGS. 5A, 5B and 5C illustrate the thickness, bandgap and refractive index of a cavity of the VCSEL of FIG. 4.

FIG. 6 is a schematic illustration of the bandgap and electric field distribution in a VCSEL similar to that shown in FIG. 4.

FIG. 7 is a schematic illustration of an alternative structure of a λ/2 cavity VCSEL.

### DETAILED DESCRIPTION

The features which define a “high speed” VCSEL include one or more of the following:
High-frequency modulation for opto-electronic components such as a laser >1 GHz. Frequencies now 10 GHz, >25 GHz
Low external parasitics: especially low Bondpad capacitance (<1 pF) and low device resistance (<100 Ohm)
Low internal parasitics of mesa, oxide layer, cavity
Sufficiently low mode volume and good carrier and optical mode confinement (typically by oxide aperture diameter <15 μm)
Sufficiently high output power (order of magnitude mW)
Sufficiently high gain and differential gain (as for example in 8 nm GaAs/AlGaAs QWs, but also other materials could be used)
Sufficient separation of operating point current versus threshold current: Min 3× Ith, typical 5-10× Ith
Preferred operating point in the linear LI region
Small rise and fall times of optical response to electrical excitation (Example: 10 GBit/s: Rise time: 40 ps, Fall time: 45 ps)
Small photon and carrier lifetimes and low threshold current (typically <2 mA)
Low power consumption (<25 mW), high wall-plug efficiency (>10%)
Preferred multi-mode operation (see U.S. Pat. No. 5,359,477)
Low spectral linewidth (nm range)
High reliability for commercial use (wear-out after several years under normal operating conditions)

In order to overcome limitations which “slow down” the high speed operation of the VCSEL, it is proposed to reduce the cavity size to λ/2. A structure of a VCSEL having such a cavity is shown in FIG. 4. The structure of the VCSEL 400 includes a substrate 401 on which an n-doped mirror 402 is formed by alternating layers of high refractive index material 403 and low refractive index material 404 so as to produce a high reflectivity Distributed Bragg Reflector (DBR). A p-doped mirror 405, also formed as a DBR by alternating high and low refractive index layers 403, 404, is located above the n-doped mirror 402, with a cavity 406 formed therebetween. The cavity includes an active (gain) region 407 comprising one or more quantum well layers separated by barrier layers. An oxide layer 408 defining an aperture 409 is located between the cavity 406 and the p-mirror 405. In this example it can be seen that the oxide layer 408 and p-mirror 405 form a mesa. The VCSEL 400 also includes a cap layer 410 on top of the p-mirror 405.

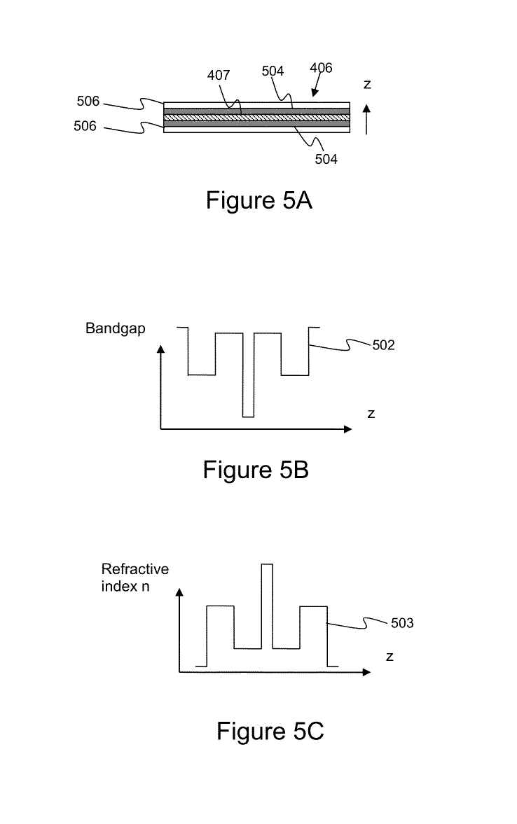

FIG. 5A illustrates the thickness of the cavity 406 of the VCSEL of FIG. 4. The cavity 406 includes the active region 407 sandwiched by two barrier layers 504. A semiconductor material 504 is also formed immediately adjacent the barrier layers 504. The barrier layers include high Al content.

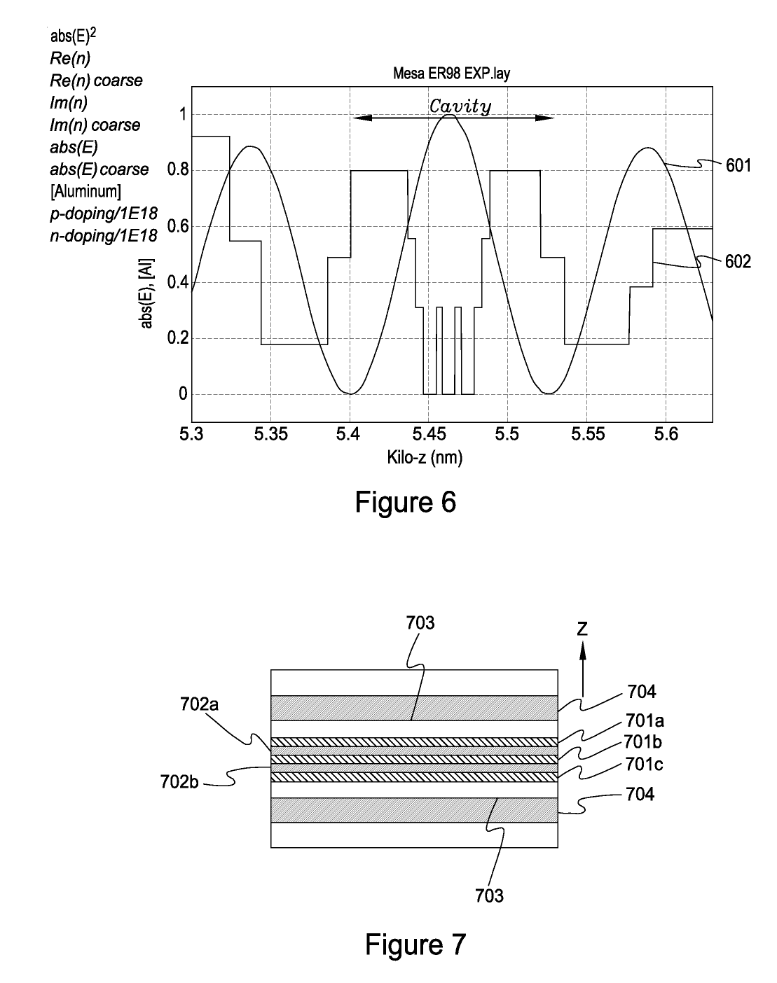

FIGS. 5B and 5C illustrate the bandgap 502 and refractive index 503 of the cavity of the VCSEL of FIG. 4. The material used to form the cavity 406 is a relatively high bandgap, low refractive index material as shown in FIGS. 5A-5C. This is thus an “inverted cavity” and an electric field distribution 601 with the bandgap 602 of such a cavity is shown in FIG. 6.

It will be noted that, in FIGS. 5A and 5B, the bandgap energy of each barrier layer 504 either side of the active region 407 of the cavity 406 is lower than that of the semiconductor 506 immediately adjacent to it. The difference in bandgap energy in the barrier 504 compared to the adjacent semiconductor 506 should be at least 2 kT, preferably 5 kT or more, and more preferably still 10 kT or more, where k is the Boltzmann constant and T is the temperature, which in most situations will be of the order of 300 K. This leads to a higher carrier confinement in the active region 407.

FIG. 7 is a schematic illustration of an alternative structure of a λ/2 cavity VCSEL. In this example the cavity 700 includes three active regions (quantum wells) 701a, 701b, 701c separated by two barrier layers 702a, 702b. A narrow buffer layer 703 is also formed between the active regions 701a, 701b, 701c and a low index material 704 in the cavity 700. It will be appreciated that the buffer layer 703 will typically be 10 nm or less in thickness.

The use of a cavity of the type shown in FIGS. 4 to 7, in a VCSEL is unusual. Conventional edge-emitting lasers are formed as PIN junctions in such a way that the laser light is propagated through the Intrinsic (I) layer having a low band gap and high refractive index. VCSELs have traditionally been constructed on the same principle. However, because the cavity is grown rather than being part of the same layer that generates the light, it is possible to make a cavity from low refractive index material.

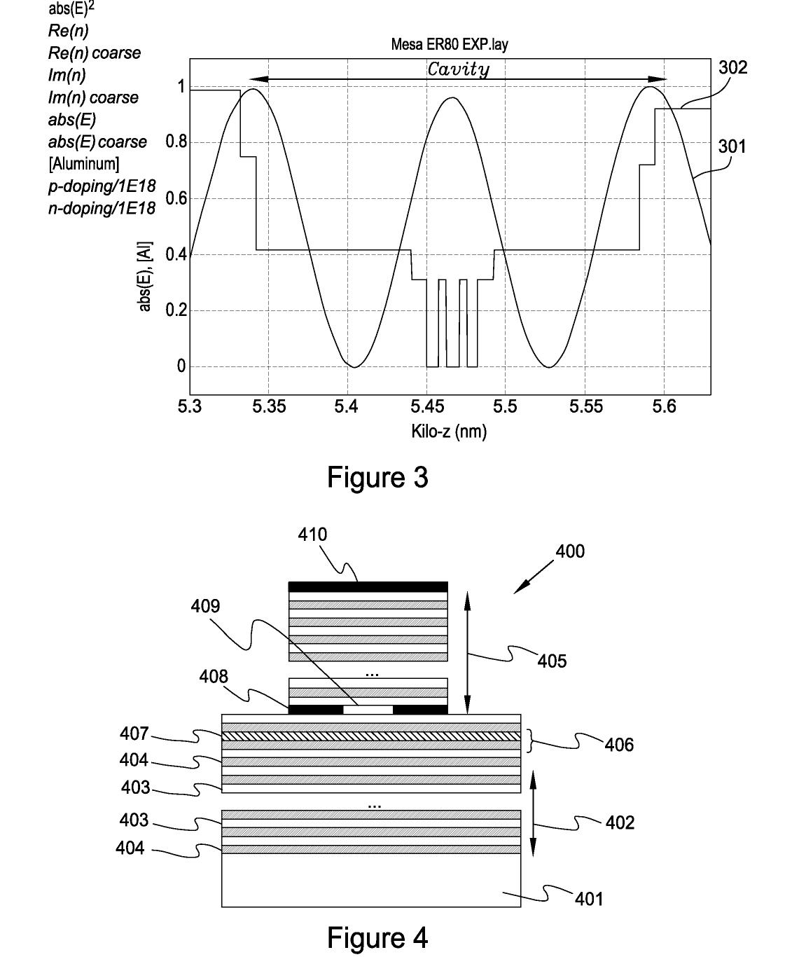

In traditional VCSELs having λ cavities, the cavity length is typically 200-300 nm and made of intrinsic material. Because the refractive index is high, the mirrors are at wave anti-nodes (as shown in FIG. 3). The use of a low refractive index material enables the mirrors to be at wave nodes (as shown in FIG. 6) and it is this which enables the cavity to have length λ/2.

A VCSEL is effectively a p-n junction, and a population inversion in the junction is needed to operate the device. In order to modulate the photonic field transmitted by the device, the carrier population in the cavity must be modulated. The field modulation responds to the carrier modulation in a manner similar to a coupled pendulum.

For a high speed device a very fast response of the photonic field is required. A λ/2 high bandgap/low refractive index cavity has fewer carriers than a conventional A cavity, and this makes it possible to modulate the carriers much more quickly (because there are fewer electrons/holes created under lasing conditions and fewer holes to fill when lasing is switched off).

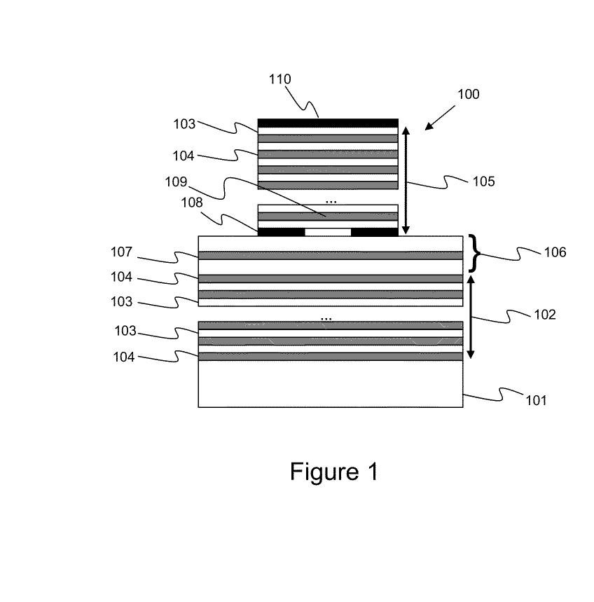

It will be noted that, in most other respects the high speed VCSEL shown in FIG. 4 is similar to that shown in FIG. 1. In particular, the materials of the cavity are not oxidised. This allows the increase in speed of the VCSEL to come about without a corresponding decrease in reliability. If the VCSEL is based on the AlGaAs/GaAs system, the material composition of the cavity needs to be at least 1% less than the oxide layer composition.

The use of an inverted λ/2 cavity results in faster carrier transport, an enhanced interaction between photon and carrier populations in the active region, and a lower photon lifetime compared to a conventional high speed VCSEL. These effects make the VCSEL faster (higher modulation bandwidth). The low refractive index material in the cavity has a higher energy gap with also helps to confine the carriers (especially electrons) in the active region. This also improves the temperature behaviour of a VCSEL. This type of VCSEL design therefore has significant advantages in a high frequency datacom VCSEL.

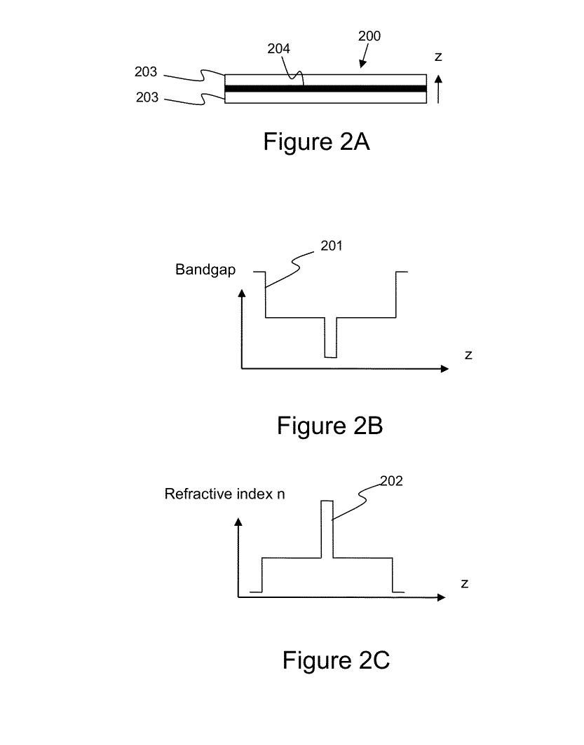

There are other advantages displayed in a λ/2 cavity. The long “buffer” 203 between the area with high bandgap (and Al content) and the quantum wells shown in FIGS. 2A and 2B is no longer present. Instead, the distance between the edge of the active region (quantum wells) 407 and the region having high Al content 504 (and thus high bandgap and low refractive index) may be 10 nm or even less on both sides of the active region (shown in FIGS. 5A and 5B). This introduces strain into the quantum wells and this results in further improvements in the speed of the device.

In a traditional λ cavity (shown in FIGS. 2A to 2C), all of the high refractive index material 203 which forms the cavity has a low Al content, resulting in a low lattice mismatch to the quantum well 204, and it is this which enables the cavity material to act as a stress relief buffer layer. In a GaAs system this means that there is a layer of 120 nm or more between the active region 204 and the “next” high AlGaAs. On the contrary, in a λ/2 cavity (shown for example in FIGS. 5A to 5C), this buffer layer with its low lattice mismatch is not present and the active region 407 is sandwiched between two high AlGaAs layers 504 with a gap of 10 nm or less.

By using a λ/2 cavity it is possible to increase the VCSEL bandwidth by more than 5 GHz using the same active region material (GaAs) as in a previous lambda cavity design. This design shows good reliability and high speed. It may also increase the bandwidth of VCSELs with a strained active region, such as for example InGaAs. It will be appreciated that the quantum wells in the active region may be formed from GaAs, AlGaAs, GalnAs, AlGaInAsP, or similar materials.

If the device is built on a GaAs substrate it is possible to produce wavelengths in the range from about 650 nm to about 1.5 μm, depending on the material used in the active region. In general, 850 nm is the preferred wavelength for fibre communication.

Thus the arrangements described above include the following features compared to a conventional VCSEL:
Lower active volume in the inverted λ/2 cavity
Reduction of carrier transport delay to quantum wells
Reduction of active region carrier number outside the quantum well (=buffered carriers). This can lead to elimination of the buffer layer
Higher electric field overlap with quantum wells: higher stimulated emission rate, lower threshold
Lower photon lifetime leading to less damping and higher speed

While the foregoing is directed to embodiments of the present invention, other and further embodiments of the invention may be devised without departing from the basic scope thereof, and the scope thereof is determined by the claims that follow.

1. A high speed vertical-cavity surface-emitting laser, VCSEL, comprising:
a substrate;
first and second distributed Bragg reflectors, DBRs, disposed on the substrate, each comprising a stack of layers of alternating refractive index;
a resonant cavity disposed between the DBRs; and
an active region disposed in the resonant cavity;
wherein the resonant cavity is formed of material having low refractive index and has an optical thickness in a direction perpendicular to the substrate of ½λ, where λ is the wavelength of light emitted by the VCSEL such that carrier delay in the cavity is 100 ps or less.

2. The high speed VCSEL of claim 1, fabricated using the AlGaAs/GaAs system.

3. The high speed VCSEL of claim 2, wherein the cavity is formed from Al doped material.

4. The high speed VCSEL of claim 3, wherein the aluminium material composition of the cavity is at least 1% less than the aluminium composition of the oxide layer.

5. The high speed VCSEL of claim 1, fabricated using the InGaAsP/GaAs system.

6. The high speed VCSEL of claim 1, wherein the distance between the active region and the low refractive index material in the cavity is in the range 0 to 50 nm, preferably 0 to 25 nm, more preferably 5-15 nm.

7. The high speed VCSEL of claim 1, wherein the active region includes strained quantum wells.

8. The high speed VCSEL of claim 1, wherein at least one oxide layer is included in either or both of the DBRs.

9. The high speed VCSEL of claim 1, wherein the cavity is disposed between two barrier layers, each barrier layer having a bandgap energy which is less than that of the surrounding low refractive index material of the cavity by a difference of at least 2 kT, preferably at least 5 kT, more preferably at least 10 kT.

10. The high speed VCSEL of claim 1, wherein the cavity does not include an oxide material.

11. The high speed VCSEL of claim 1, configured so that it is capable of emitting light modulated at a rate of at least 5 Gbit/s, preferably at least 10 Gbit/s, more preferably at least 15 Gbit/s, more preferably at least 25 Gbit/s.

12. The high speed VCSEL of claim 1, configured to emit light having a wavelength in the range 670 nm to 1500 nm, preferably about 850 nm.

13. A method of generating modulated light, comprising:
injecting current into an active region of a high speed VCSEL, the active region located in a resonant cavity disposed between first and second DBRs, the cavity being formed of material having low refractive index and having an optical thickness of ½λ, where λ is the wavelength of light emitted by the VCSEL; and
modulating the current such that the rise/fall time of a change in current is 100 ps or less.
